(19) United States
(12) Patent Application Publication
(10) Pub. No.: US 2025/0089488 A1
(43) Pub. Date: Mar. 13, 2025

(54) DISPLAY PANEL AND DISPLAY APPARATUS

(71) Applicants: Chongqing BOE Display Technology Co., Ltd., Chongqing (CN); BOE TECHNOLOGY GROUP CO., LTD., Beijing (CN)

(72) Inventor: Xuebin YUAN, Beijing (CN)

(21) Appl. No.: 18/286,803

(22) PCT Filed: Nov. 30, 2022
(86) PCT No.: PCT/CN2022/135315

§ 371 Date: Oct. 13, 2023

(51) Int. Cl. H10K 59/131; H10K 59/80

(52) U.S. Cl. CPC H10K 59/131; H10K 59/80515

(57) ABSTRACT

The present disclosure provides a display panel and a display apparatus, the display panel includes a display region and a non-display region surrounding the display region, the display panel includes a light emitting device having a first electrode, the first electrode includes an in-plane electrode in the display region and an out-of-plane electrode in the non-display region, and a voltage dividing structure, and the voltage dividing structure is connected between the in-plane electrode and the out-of-plane electrode, and a resistivity of a material of the voltage dividing structure is greater than that of a material of each of the out-of-plane electrode and the in-plane electrode. The display panel provided by the present disclosure can improve the display brightness uniformity without increasing a width of the non-display region of the display panel.

### TECHNICAL FIELD

The present disclosure relates to the field of display technology, and in particular to a display panel and a display apparatus.

### BACKGROUND

In a current-type display device, as for an OLED (organic light emitting diode) or a mini LED/micro LED, it is necessary to apply voltages to a cathode and an anode of the display device to make it emit light. Due to a size limitation of a medium-sized or small-sized product, in order to ensure a high pixel density and a high brightness, it is required that voltage transmission traces do not shield the light emitting device as much as possible. By taking a top emission OLED device as an example, a voltage on its anode is generally provided by an in-plane mesh metal trace, and a voltage on its cathode is provided through an external cathode ring and then is introduced into an in-plane cathode through a full-surface material having a light-transmitting property. The peripheral cathode ring needs to transmit input signals for all pixel regions, the total current passing through the peripheral cathode ring is very high, and the cathode ring is usually arranged at the periphery of the display panel (namely, in a non-display region), so that for the medium-sized or small-sized product, a peripheral width of the display panel needs to be as small as possible, which results in the fact that the cathode ring has a higher resistance due to a narrow width and a voltage drop (IR drop) of the cathode ring is very serious. When the display panel outputs a high-brightness picture, voltages input into the in-plane cathode through the cathode ring are different in different pixel regions due to the voltage drop, which reduces the display brightness uniformity.

### SUMMARY

The present disclosure is directed to solve at least one of the problems in the prior art, and provides a display panel and a display apparatus, which can improve the uniformity of the display brightness without increasing a width of a non-display region of the display panel.

To achieve the above object, embodiments of the present disclosure provide a display panel, including a display region and a non-display region surrounding the display region, wherein the display panel includes a light emitting device including a first electrode, the first electrode includes an in-plane electrode in the display region and an out-of-plane electrode in the non-display region, and a voltage dividing structure, wherein the voltage dividing structure is connected between the in-plane electrode and the out-of-plane electrode, and a resistivity of a material of the voltage dividing structure is greater than that of a material of each of the out-of-plane electrode and the in-plane electrode.

In some embodiments, the voltage dividing structure is arranged such that voltage drops from a signal input terminal of the out-of-plane electrode to a plurality of signal output terminals corresponding to a plurality of different positions of the in-plane electrode in a circumferential direction of the in-plane electrode are the same.

In some embodiments, the voltage dividing structure includes a plurality of resistive elements at intervals along an extending direction of the out-of-plane electrode, and one end of each of the plurality of resistive elements is connected to the out-of-plane electrode, and the other end of each of the plurality of resistive elements is the signal output terminal connected to the in-plane electrode at a corresponding one of the plurality of different positions in the circumferential direction of the in-plane electrode.

In some embodiments, a resistance of each of the plurality of resistive elements is a first resistance, and the first resistances of the plurality of the resistive elements are the same and arranged at equal intervals; and a resistance of the out-of-plane electrode on a path from the signal input terminal of the out-of-plane electrode to each of the plurality of signal output terminals is a second resistance.

In some embodiments, at least some of the plurality of resistive elements have different resistances and are arranged at equal intervals; or at least some of the plurality of resistive elements have different resistances and are arranged at unequal intervals.

In some embodiments, the out-of-plane electrode is a closed ring or a rectangular ring with an opening on a side; at least some resistive elements corresponding to at least one side of the rectangular ring has different resistances.

In some embodiments, orthographic projections of the at least some resistive elements corresponding to the at least one side of the rectangular ring on a plane parallel to the display region have different areas; and a shape of an orthographic projection of each of the plurality of resistive elements on the plane parallel to the display region includes a bar shape, and the at least some resistive elements corresponding to the at least one side of the rectangular ring have the same length in an extending direction of each resistive element but have different widths.

In some embodiments, a shape of an orthographic projection of each of the plurality of resistive elements on the plane parallel to the display region includes a bar shape, including a straight line and/or a meander line.

In some embodiments, the meander line includes a plurality of straight line segments sequentially connected; an angle between every two adjacent straight line segments is equal to 90°; and one of every two adjacent straight line segments is perpendicular to the extending direction of the out-of-plane electrode and the other one of every two adjacent straight line segments is parallel to the extending direction of the out-of-plane electrode; or the angle between every two adjacent straight line segments is less than or equal to 90°; and the angle between each of every two adjacent straight line segments and the extending direction of the out-of-plane electrode is less than 90°.

In some embodiments, the meander line includes a plurality of arc segments connected sequentially, and every two adjacent arc segments constitute an S-shaped arc segment.

In some embodiments, the number of the plurality of resistive elements is 10 or more; an equivalent resistance formed by the plurality of resistive elements connected in parallel is more than or equal to 2Ω; and a resistance of each resistive element is more than or equal to 2000Ω.

In some embodiments, the out-of-plane electrode includes one outer electrode circumferentially extending along a contour of the in-plane electrode, and the voltage dividing structure is connected between the outer electrode and the in-plane electrode.

In some embodiments, the out-of-plane electrode includes a plurality of outer electrodes at intervals sequentially in a direction away from the in-plane electrode, each outer electrode extends circumferentially along a contour of the in-plane electrode; and the outer electrode closest to the in-plane electrode is connected to the in-plane electrode; and the voltage dividing structure is connected between every two adjacent outer electrodes.

In some embodiments, the plurality of outer electrodes include at least one first outer electrode and at least one second outer electrode, the at least one first outer electrode is a closed rectangular ring; the at least one second outer electrode is a rectangular ring with an opening on a side, and the openings corresponding to different second outer electrodes have the same orientation.

In some embodiments, the outer electrode farthest from the in-plane electrode includes a signal input portion having one end connected to one side of the rectangular ring and the other end serving as the signal input terminal.

In some embodiments, the outer electrode farthest from the in-plane electrode is the first outer electrode; the number of the signal input portions is one, and one end of the signal input portion is connected to the middle of one side of the rectangular ring; or the number of the signal input portions is two, and ends of the two signal input portions on a same side are connected to two adjacent corners of the rectangular ring, respectively, and the other ends of the two signal input portions are the signal input terminals.

In some embodiments, the outer electrode farthest from the in-plane electrode is the second outer electrode; the number of the signal input portions is one, and one end of the signal input portion is connected to one of two ends of the rectangular ring adjacent to the opening; or the number of the signal input portions is two, ends of the two signal input portions on a same side are connected to two ends of the rectangular ring adjacent to the opening, and the other ends of the two signal input portions are the signal input terminals.

In some embodiments, the light emitting device further includes: a base; and a second electrode and an organic functional layer; wherein the second electrode, the organic functional layer and the in-plane electrode are all in the display region and are sequentially stacked on a side of the base along a direction away from the base; wherein the first electrode is one of a cathode and an anode, and the second electrode is the other of the cathode and the anode.

In some embodiments, each resistive element and two outer electrodes connected to the resistive element are in the same layer, and a part of the two outer electrodes connected to the resistive element is stacked on a side of the resistive element away from the base; or each resistive element and the two outer electrodes connected to the resistive element are in different layers, and two ends of the resistive element are respectively stacked on a side of the two outer electrodes connected to the resistive element away from the base.

In some embodiments, the plurality of resistive elements are divided into two layers in a direction perpendicular to a plane where the base is located, wherein the resistive element in one layer and two outer electrodes connected to the resistive element are in the same layer, and a part of the two outer electrodes connected to the resistive element is stacked on the side of the resistive element away from the base; the resistive element in the other layer and two outer electrodes connected to the resistive element are in different layers, and two ends of the resistive element are respectively stacked on a side of the two outer electrodes connected to the resistive element away from the base.

In some embodiments, the display panel further includes an encapsulation layer covering the display region and the non-display region, and the in-plane electrode and the out-of-plane electrode are on two sides of the encapsulation layer away from and close to the base, respectively; and the encapsulation layer further includes a plurality of vias, and the in-plane electrode is connected to the outer electrode closest to the in-plane electrode through the plurality of vias.

In some embodiments, the light emitting device further includes: a base; a second electrode and an organic functional layer; wherein the second electrode, the organic functional layer and the in-plane electrode are all in the display region and are sequentially stacked on a side of the base along a direction away from the base; wherein the first electrode is one of a cathode and an anode, and the second electrode is the other of the cathode and the anode; and an encapsulation layer covering the display region and the non-display region, and the in-plane electrode and the out-of-plane electrode are on two sides of the encapsulation layer away from and close to the base, respectively; wherein the encapsulation layer further includes a plurality of vias, and the in-plane electrode is connected to the voltage dividing structure through the plurality of vias.

In some embodiments, the resistive element and the outer electrode are in the same layer, and a part of the outer electrode is stacked on a side of the resistive element away from the base; or the resistive element and the outer electrode are in different layers, and one end of the resistive element is stacked on a side of the outer electrode away from the base.

In some embodiments, the plurality of resistive elements are divided into two layers in a direction perpendicular to a plane where the base is located, wherein the resistive element in one layer and the outer electrode are in the same layer, and a part of the outer electrode is stacked on the side of the resistive element away from the base; the resistive element in the other layer and the outer electrode are in different layers, and one ends of the resistive element is stacked on a side of the outer electrode away from the base.

In some embodiments, a material of the resistive element includes ITO.

As another technical solution, the present disclosure further provides a display apparatus, which includes the display panel provided by the present disclosure.

### BRIEF DESCRIPTION OF DRAWINGS

FIG. 1 is a schematic diagram of a structure of a single cathode ring and an in-plane electrode in the prior art;

FIG. 2 is a schematic diagram of a first structure of an out-of-plane electrode and an in-plane electrode of a display panel according to embodiments of the present disclosure;

FIG. 3 is a schematic diagram of a second structure of an out-of-plane electrode and an in-plane electrode of a display panel according to embodiments of the present disclosure;

FIG. 4A is a schematic diagram of a first structure of a resistive element according to embodiments of the present disclosure;

FIG. 4B is a schematic diagram of a second structure of a resistive element according to embodiments of the present disclosure;

FIG. 4C is a schematic diagram of a third structure of a resistive element according to embodiments of the present disclosure;

FIG. 4D is a schematic diagram of a fourth structure of a resistive element according to embodiments of the present disclosure;

FIG. 5 is a schematic diagram of a structure in a corner region of an in-plane electrode away from a signal input terminal according to embodiments of the present disclosure;

FIG. 6A is a schematic diagram of a third structure of an out-of-plane electrode and an in-plane electrode of a display panel according to embodiments of the present disclosure;

FIG. 6B is a schematic diagram of a fourth structure of an out-of-plane electrode and an in-plane electrode of a display panel according to embodiments of the present disclosure;

FIG. 7A is a schematic diagram of a fifth structure of an out-of-plane electrode and an in-plane electrode of a display panel according to embodiments of the present disclosure;

FIG. 7B is a schematic diagram of a sixth structure of an out-of-plane electrode and an in-plane electrode of a display panel according to embodiments of the present disclosure;

FIG. 7C is a schematic diagram of a seventh structure of an out-of-plane electrode and an in-plane electrode of a display panel according to embodiments of the present disclosure;

FIG. 7D is a schematic diagram of an eighth structure of an out-of-plane electrode and an in-plane electrode of a display panel according to embodiments of the present disclosure;

FIG. 7E is a schematic diagram of a ninth structure of an out-of-plane electrode and an in-plane electrode of a display panel according to embodiments of the present disclosure;

FIG. 7F is a schematic diagram of a tenth structure of an out-of-plane electrode and an in-plane electrode of a display panel according to embodiments of the present disclosure;

FIG. 8 is a schematic diagram of an eleventh structure of an out-of-plane electrode and an in-plane electrode of a display panel according to embodiments of the present disclosure;

FIG. 9A is a first partial cross-sectional view of a display panel according to embodiments of the present disclosure;

FIG. 9B is a second partial cross-sectional view of a display panel according to embodiments of the present disclosure;

FIG. 9C is a third partial cross-sectional view of a display panel according to embodiments of the present disclosure;

FIG. 10 is a graph of a uniformity of an in-plane display brightness as a function of an equivalent resistor of a plurality of resistive elements connected in parallel;

FIG. 11A is a schematic diagram showing a distribution of a display brightness of a display panel using the cathode ring shown in FIG. 1 in the prior art; and

FIG. 11B is a schematic diagram showing a distribution of a display brightness of a display panel employing two external electrodes and a voltage dividing structure according to embodiments of the present disclosure.

### DETAIL DESCRIPTION OF EMBODIMENTS

In order to make the objects, technical solutions and advantages of the present invention more apparent, the present invention will be described in further detail with reference to the accompanying drawings. Obviously, the described embodiment is only a part, not all, of the embodiments in the present invention. All other embodiments, which can be obtained by a person skilled in the art without any creative effort based on the embodiments in the present invention, belong to the protection scope of the present invention.

Shapes and sizes of the components in the drawings are not to scale, but are merely intended to facilitate an understanding of the contents of the embodiments of the present invention.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

The disclosed embodiments are not limited to the embodiments shown in the drawings, but include modifications of configurations formed based on a manufacturing process. Thus, areas illustrated in the drawings have schematic properties, and shapes of the areas shown in the drawings illustrate specific shapes of the areas of elements, but are not intended to be limiting.

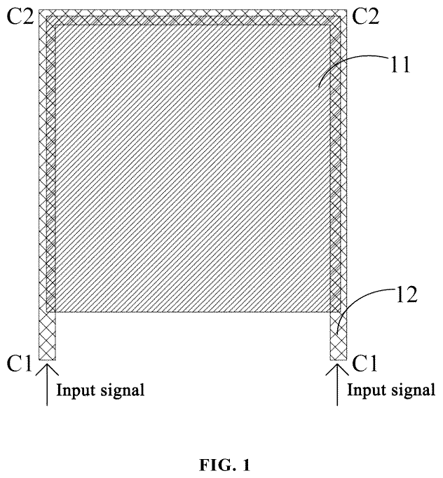

As described in the background, the display panel has the problem of the poor display brightness uniformity in the art. The inventor has found through research that the reason is as follow: by taking a light emitting device in the display panel as a top emission OLED device as an example, as shown in FIG. 1, a full-surface (planar) cathode 11 is provided in a display region of the display panel, and a cathode ring 12 (not closed) is provided in a non-display region of the display panel, and surrounds the full-surface cathode 11 and is electrically connected to the full-surface cathode 11. The cathode ring 12 has two signal input terminals C1. The cathode ring 11 has different resistance values from the signal input terminal C1 to different positions on a path away from the signal input terminal (for example, from C1 to C2), so that the cathode ring 12 has different voltage drops (IR drops) on the path for transmitting the input signal to the full-surface cathode 11, and the resistance value is larger and the voltage drop is larger at the position farther away from the signal input terminal C1, which causes the current difference in different pixel regions, i.e., the display brightness difference, and thus the display panel has the problem of the poor display brightness uniformity.

In view of this, embodiments of the present disclosure provide a display panel. The display panel includes a display region and a non-display region surrounding the display region, wherein the display panel includes a light emitting device, including a base, a first electrode, a second electrode and an organic functional layer, and the second electrode, the organic functional layer and the first electrode are sequentially stacked on a side of the base along a direction away from the base. The light emitting device is, for example, an OLED device, which may be a top emission OLED device or a bottom emission OLED device. For the top emission OLED device, the first electrode is a cathode and the second electrode is an anode. For the bottom emission OLED device, the first electrode is an anode and the second electrode is a cathode.

In some embodiments, for the top emission OLED device, the organic functional layer may include, for example, a hole injection layer, a hole transport layer, a light emitting layer, an electron transport layer, and an electron injection layer sequentially stacked in the direction away from the base, wherein the hole injection layer, the hole transport layer, the light emitting layer, the electron transport layer, and the electron injection layer are sequentially electrically connected to each other, the hole injection layer is electrically connected to the anode, and the electron injection layer is electrically connected to the cathode. Alternatively, in practical applications, the organic functional layer may also adopt other structures, which is not particularly limited in this embodiment of the present disclosure.

In some embodiments, for the bottom emission OLED device, the organic functional layer includes, for example, an electron injection layer, an electron transport layer, a light emitting layer, a hole transport layer, and a hole injection layer, which are sequentially stacked along the direction away from the base, where the electron injection layer is electrically connected to the cathode, and the hole injection layer is electrically connected to the anode. Alternatively, in practical applications, the organic functional layer may also adopt other structures, which is not particularly limited in this embodiment of the present disclosure.

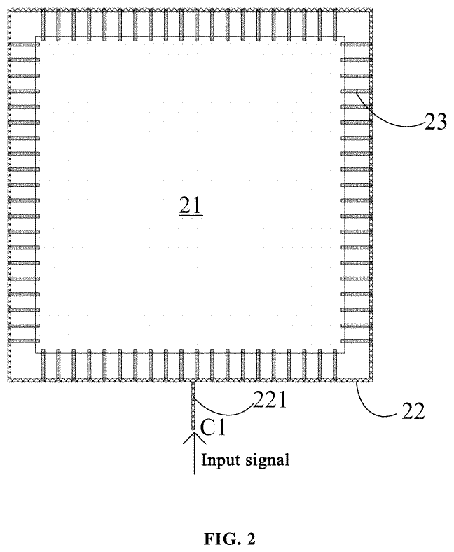

Specifically, referring to FIG. 2, the first electrode includes an in-plane electrode 21 located in the display region and an out-of-plane electrode located in the non-display region, and a voltage dividing structure connected between the in-plane electrode 21 and the out-of-plane electrode, where the in-plane electrode 21 is, for example, a full-surface electrode covering the entire display region, which has a light-transmitting property and is used for providing a voltage to each pixel region. When the first electrode is a cathode, the in-plane electrode is electrically connected to the electron injection layer. When the first electrode is an anode, the in-plane electrode is electrically connected to the hole injection layer.

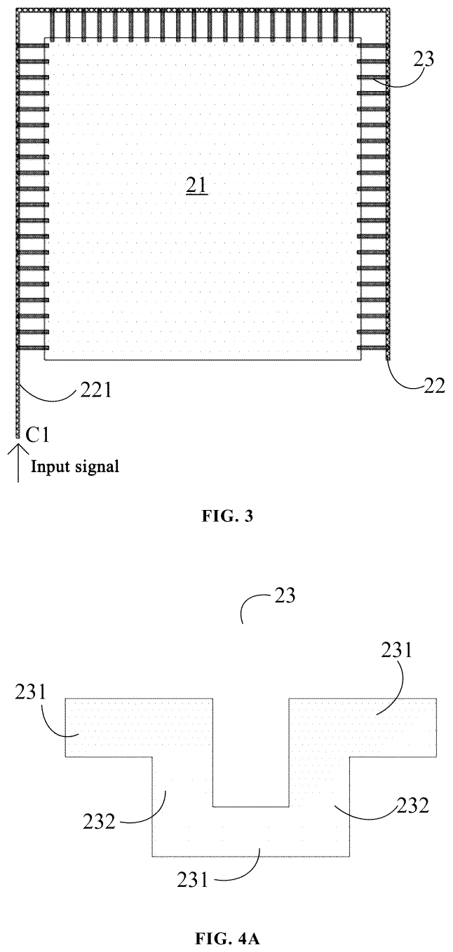

In this embodiment, the out-of-plane electrode includes an outer electrode 22 extending circumferentially along a contour of the in-plane electrode 21. Specifically, the outer electrode 22 may circumferentially surround the in-plane electrode 21 along the contour of the in-plane electrode 21, thereby forming a closed ring, as shown in FIG. 2. In some embodiments, a shape of a contour of the closed ring matches a shape of a contour of the in-plane electrode, and the closed ring is disposed equidistantly from the in-plane electrode 21. Alternatively, the outer electrode 22 may also extend circumferentially along the contour of the in-plane electrode, but does not completely surround the in-plane electrode, thereby forming a non-closed ring with an opening, as shown in FIG. 3. In some embodiments, a shape of a contour of the non-closed ring matches with a shape of a contour of the in-plane electrode, and the non-closed ring is disposed equidistantly from the in-plane electrode 21. For example, the shape of the contour of the in-plane electrode 21 is rectangular, and the shape of the contour of the closed ring or the non-closed ring is rectangular. In practical applications, the shape of the contour of the in-plane electrode 21 may also be a square shape or any other shape, and may be set according to the shape of the contour of the in-plane electrode, which is not particularly limited in the embodiment of the present disclosure.

The voltage dividing structure is connected between the outer electrode 22 and the in-plane electrode 21, and a resistivity of a material of the voltage dividing structure is greater than that of the out-of-plane electrode and the in-plane electrode. By having the resistivity of the material of the voltage dividing structure greater than that of the out-of-plane electrode and the in-plane electrode, a total resistance on paths from an signal input terminal of the out-of-plane electrode to signal output terminals (i.e., the terminals at which the respective resistive elements 23 are connected to the in-plane electrode 21) may be approximately equal to an equivalent resistance of the voltage dividing structure, i.e., the difference in resistance among the paths corresponding to the respective signal output terminals can be compensated for, and further the voltage drops (IR drops) from the signal input terminal of the out-of-plane electrode to the plurality of signal output terminals corresponding to a plurality of different positions of the in-plane electrode 21 in the circumferential direction thereof can be substantially the same, whereby the display brightness uniformity can be improved.

Further in some embodiments, the voltage dividing structure may be arranged so that the voltage drops (IR drops) from the signal input terminal C1 of the out-of-plane electrode to the plurality of signal output terminals corresponding to the plurality of different positions of the in-plane electrode 21 in the circumferential direction thereof are the same. Therefore, the difference for the voltage drop of the out-of-plane electrode on the path of transmitting the input signal to the in-plane electrode 21 can be eliminated, the current difference in different pixel regions (that is, the display brightness difference) can be eliminated, and the display brightness uniformity can be improved. Meanwhile, the out-of-plane electrode does not increase the width of the non-display region of the display panel on the whole, so that the narrow frame is realized.

There may be various voltage dividing structures for realizing the above functions, for example, the voltage dividing structure includes a plurality of resistive elements 23 disposed at intervals along an extending direction of the out-of-plane electrode (i.e., the outer electrode 22), and one end of each of the plurality of resistive elements 23 is connected to the out-of-plane electrode (i.e., the outer electrode 22), and the other end of each of the plurality of resistive elements 23 serves as the signal output terminal connected to the in-plane electrode 21 at a plurality of different positions in the circumferential direction thereof. By means of the resistive element 23, the resistance on the path from the signal input terminal C1 to each signal output terminal can be increased, and the resistance difference among the paths corresponding to the signal output terminals can be compensated for, so that the difference for the voltage drop of the out-of-plane electrode (i.e., the outer electrode 22) on the path for transmitting the input signal to the in-plane electrode 21 can be eliminated, the current difference in different pixel regions can be eliminated, and the display brightness uniformity can be improved.

In some optional embodiments, the material of the resistive element 23 includes ITO. Alternatively, in practical applications, the resistive element 23 may be made of any other conductive material, and preferably, be made of a material with a relatively high resistance, which is not particularly limited in the embodiment of the present disclosure.

In some optional embodiments, the outer electrode 22 includes multiple metal layers of different thicknesses, such as three metal layers, which are sequentially Ti, Al, and Ti in a direction away from the base. The metal layers are preferably made of materials with a small sheet resistance. Alternatively, in practical applications, the outer electrode 22 may also include one metal layer or two or four or more metal layers.

The plurality of resistive elements 23 may compensate for the resistance difference among the paths corresponding to the signal output terminals in various manners. For example, in a first manner, a resistance of each of the plurality of resistive elements 23 is a first resistance R, and the first resistances R of the plurality of resistive elements 23 are the same and are arranged at equal intervals. A resistance of the out-of-plane electrode (i.e., the outer electrode 22) on the path from the signal input terminal C1 of the out-of-plane electrode to a terminal at which the out-of-plane electrode 22 is connected to each resistive element 23 is a second resistance ri, i=1, 2, . . . , N, N is the number of the resistive elements 23. The first resistance R is greater than the second resistance ri. Since the total resistance on the paths from the signal input terminal of the out-of-plane electrode to the signal output terminals (i.e., the terminals at which the respective resistive elements 23 are connected to the in-plane electrode 21) is equal to the sum of the first resistance R and the second resistance ri, by having the first resistance R of each of the plurality of resistive elements 23 greater than the second resistance ri, preferably, the first resistance R is much greater than the second resistance ri (R>>ri), a difference among the different second resistances can be small with respect to the first resistance R, and can be ignored, so that the total resistance (R+ri) on the paths corresponding to the respective signal output terminals may be approximately equal to the first resistance R, that is, the difference in resistance among the paths corresponding to the respective signal output terminals is compensated for, and further the voltage drops (IR drops) from the signal input terminal of the out-of-plane electrode to the plurality of signal output terminals corresponding to the plurality of different positions of the in-plane electrode 21 in the circumferential direction thereof can be approximately the same, so that the display brightness uniformity can be improved.

In some optional embodiments, a shape of an orthographic projection of each resistive element 23 on a plane parallel to the display region includes a bar shape, including a straight line and/or a meander line. Specifically, the bar-shaped resistive element 23 is, for example, a conductive wire having a shape of, for example, a straight conductive wire or a meander-line conductive wire or a combination of both. The longer the conductive wire in an extending direction thereof is, the greater the resistance is; the shorter the conductive wire in the extending direction thereof is, the less the resistance is. Based on this, the shape of the conductive wire and the length of the conductive wire in the extending direction thereof may be set according to the required resistance of the resistive element 23. For example, if it is required that the resistance of the resistive element 23 is small or a width and a thickness of the conductive wire are sufficient, a straight conductive wire or a combination of the straight conductive wire and a meander-line conductive wire may be selected. If it is required that the resistance of the resistive element 23 is greater or the width and the thickness of the conductive wire are small, the meander-line conductive wire may be chosen to obtain the conductive wire having a sufficient length. Alternatively, the embodiment of the present disclosure is not limited to this, and in practical applications, the resistive element may also be a resistive element with a certain resistance.

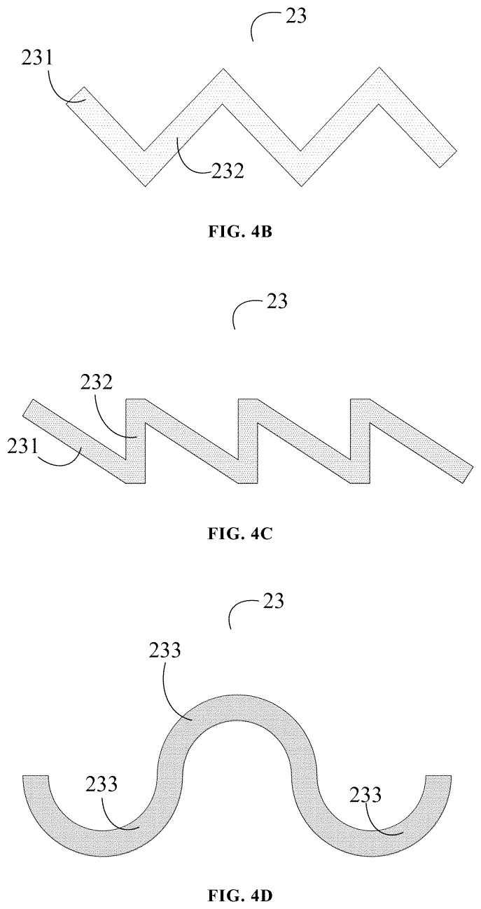

The meander line may have various shapes. For example, the meander line includes a plurality of straight line segments which are sequentially connected, and an angle between every two adjacent straight line segments is less than or equal to 90°. Further in some embodiments, as shown in FIG. 4A, an angle between every two adjacent straight line segments (231, 232) is equal to 90°, and one of every two adjacent straight line segments (i.e., a straight line segment 231) is perpendicular to an extending direction of the out-of-plane electrode and the other one of every two adjacent straight line segments (i.e., a straight line segment 232) is parallel to the extending direction of the out-of-plane electrode. Further in some embodiments, as shown in FIG. 4B, an angle between every two adjacent straight line segments (231, 232) is equal to 90°, and an angle between each of the every two adjacent straight line segments (231, 232) and the extending direction of the out-of-plane electrode is smaller than 90°, for example, is 45°. Further in some embodiments, as shown in FIG. 4C, an angle between every two adjacent straight line segments (231, 232) is smaller than 90°, for example is 30°, and an angle between each of every two adjacent straight line segments (231, 232) and the extending direction of the out-of-plane electrode is smaller than 90°, for example is 60°. Further in some embodiments, as shown in FIG. 4D, the meander line includes a plurality of arc segments 233 connected sequentially, and every two adjacent arc segments 233 form an S-shaped arc segment. Alternatively, the embodiment of the present disclosure is not limited to this. In practical applications, the meander line may also have any other shape as long as the required resistance of the resistive element can be obtained.

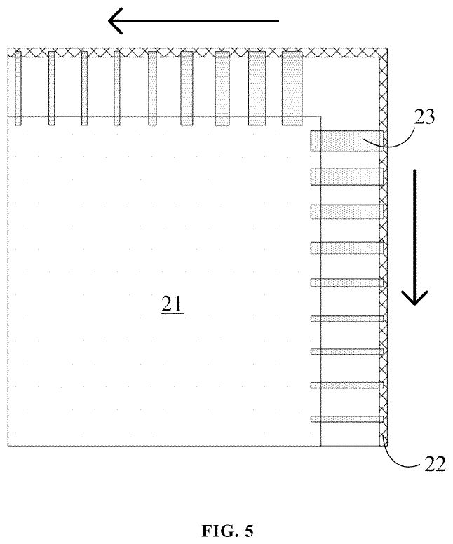

A second way of compensating for the resistance difference among the paths corresponding to the signal output terminals is that at least some resistive elements 23 have different resistances and are arranged at equal intervals; alternatively, at least some resistive elements 23 have different resistances and are arranged at unequal intervals. That is, the difference of the voltage drop between a local position with a great voltage drop and the other position is compensated for by providing at least some resistive elements 23 having different resistances. For example, as shown in FIG. 5, for the structure with the plurality of resistive elements 23 corresponding to a corner region (i.e., an upper right corner) of the rectangular in-plane electrode 21 away from the signal input terminal, the voltage drop of the corresponding outer electrode 22 at the corner region is more serious and becomes more serious as the corresponding outer electrode 22 is closer to the corner. In this case, the difference of the voltage drop between the corner region and the other position may be compensated for by increasing the resistances of some resistive elements 23 near the corner. In practical applications, the resistances of the resistive elements may be set according to the resistance difference among the paths corresponding to the signal output terminals, and may be selectively set to be arranged at equal intervals or arranged at unequal intervals.

In some optional embodiments, the out-of-plane electrode (i.e. the outer electrode) is a closed ring or a rectangular ring with an opening on a side, and is suitable for the rectangular display region. That is, for example, the ring-shaped shape of the out-of-plane electrode matches with a shape of a contour of the display region; at least some of the plurality of resistance elements 23 arranged corresponding to at least one side of the rectangular ring have different resistances. The resistance at a position farther from the signal input terminal is greater and the voltage drop is also greater, and at least some of the plurality of resistance elements 23 arranged corresponding to at least one side of the rectangular ring have different resistances, so that the resistance difference in a direction in which the side corresponding to the rectangular ring is located can be compensated for, and the difference of the voltage drop existing at the side of the rectangular ring can be eliminated. It should be noted that the out-of-plane electrode is not limited to be the rectangular ring, which may be adjusted according to the shape of the contour of the display region. For example, the out-of-plane electrode is a square ring.

The different resistances of the plurality of resistive elements 23 arranged corresponding to at least one side of the rectangular ring may be realized in various manners. For example, orthographic projections of the plurality of resistive elements 23 arranged corresponding to the side of the rectangular ring on the plane parallel to the display region have different areas. The greater the area of the orthographic projection is, the greater the resistance is; otherwise, the smaller the area of the orthographic projection is, the smaller the resistance is. Based on this, the orthographic projections of the plurality of resistive elements 23 arranged corresponding to the side of the rectangular ring on the plane parallel to the display region have different areas, so that the different resistances of the plurality of resistive elements 23 arranged corresponding to the side of the rectangular ring may be realized. Further in some embodiments, as shown in FIG. 5, a shape of an orthographic projection of each resistive element 23 on the plane parallel to the display region includes a bar shape, and the plurality of resistive elements 23 arranged corresponding to the side of the rectangular ring have the same length in the extending direction thereof but have different widths, so that the orthographic projections of the plurality of resistive elements 23 arranged corresponding to the side of the rectangular ring on the plane parallel to the display region have different areas. On this basis, the plurality of resistive elements 23 arranged corresponding to the side of the rectangular ring have the same length in the extending direction thereof, which is suitable for the case where the out-of-plane electrode is equidistant from the in-plane electrode, and is convenient for both ends of each resistive element 23 to be connected to the out-of-plane electrode and the in-plane electrode 21, respectively. Alternatively, in practical applications, the shape of the orthographic projection of each resistive element on the plane parallel to the display region may adopt any other shape, which is not particularly limited by the embodiment of the present disclosure. It should be noted that in the second manner, the different resistive elements may have the same shape and different sizes; alternatively, different resistive elements may have different shapes, which is not particularly limited by the embodiment of the present disclosure.

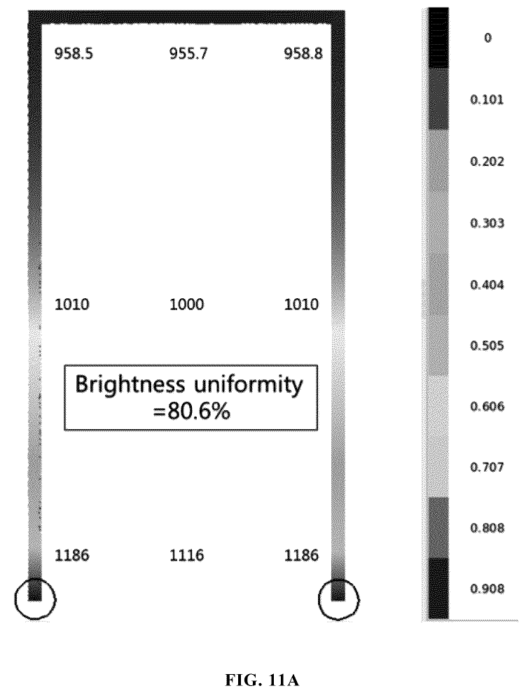

In both the first and second manners, the number of the resistive elements 23 and the resistances of the resistive elements 23 may be set to have an effect on improving the in-plane display brightness uniformity. Specifically, when a sheet resistance of the out-of-plane electrode is constant and the number of the resistive elements 23 is the same, the greater the resistance of each resistive element 23 is, the better the uniformity of the voltages of the plurality of signal output terminals corresponding to the plurality of different positions of the in-plane electrode 21 in the circumferential direction thereof is, and the better the in-plane display brightness uniformity is. In some embodiments, the resistance of each resistive element is equal to or greater than 2000Ω. When the sheet resistance of the out-of-plane electrode is constant and the resistances of the resistive elements are the same, the less the number of the resistive elements 23 is, the better the uniformity of the voltage of the in-plane electrodes 212 close to the positions connected to the resistive elements 23 is, and the better the in-plane display brightness uniformity is. The reason is as follow: it is assumed that the in-plane electrode 21 and the out-of-plane electrode are regarded as two ideal nodes A and B, and a plurality of resistive elements 23 are connected in parallel therebetween. The resistance between the two ideal nodes A and B is directly proportional to a quotient obtained by dividing the resistance of each resistive element 23 by the number of resistive elements 23, the less the number of resistive elements is, the greater the quotient is, and the greater the resistance between the two ideal nodes A and B which is directly proportional to the quotient is, and thus, the better the voltage uniformity close to the ideal node B is, and the better the in-plane display uniformity is. Further, an equivalent resistance when the plurality of resistive elements 23 are connected to each other in parallel is equal to the quotient obtained by dividing the resistance of each resistive element 23 divided by the number of resistive elements. For example, if the resistance of each resistive element 23 is 2000Ω and the number of resistive elements is 1000, the equivalent resistance is 2Ω, and the greater the equivalent resistance is, the better the voltage uniformity close to the ideal node B is, and the better the in-plane display brightness uniformity is. Referring to FIG. 10, when the resistive elements are connected in parallel, the abscissa represents the equivalent resistance, and the ordinate represents the in-plane display brightness uniformity. It can be seen from FIG. 10 that the in-plane display brightness uniformity increases as the equivalent resistance increases.

However, the number of the resistive elements 23 cannot be too small because the number of the resistive elements 23 affects the uniformity of the voltage drop of the in-plane electrode 21 among the positions connected to the resistive elements 23; the uniformity of the voltage drop of the in-plane electrode 21 among the positions connected to the resistive elements 23 is improved more remarkably as the number of the resistive elements 23 becomes greater. Otherwise, the effect of improving the voltage uniformity of the in-plane electrode 21 between the positions connected to the resistive elements 23 is reduced due to the resistance of the in-plane electrode 21. In some embodiments, the number of the resistive elements 23 is 10 or more. In practical applications, the number of the resistive elements 23 may be set according to parameters such as a size and a process requirement of the display panel, a magnitude design of the equivalent resistance, which is not particularly limited in the embodiment of the present disclosure.

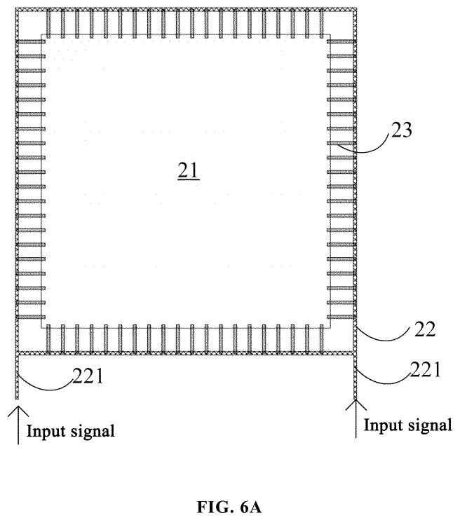

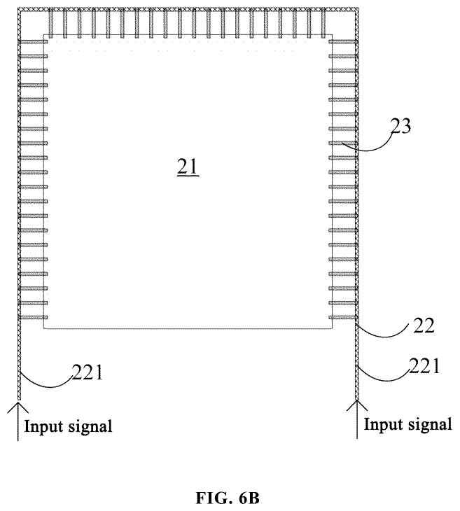

In some optional embodiments, the out-of-plane electrode (i.e., outer electrode 22) is a closed ring or a rectangular ring with an opening on a side, and is suitable for the rectangular display region. That is, for example, the ring-shaped shape of the out-of-plane electrode matches with a shape of a contour of the display region. As shown in FIGS. 2 and 3, the outer electrode 22 is provided with a signal input portion 221, one terminal of the signal input portion 221 is connected to one side of the rectangular ring, and the other terminal of the signal input portion 221 serves as the signal input terminal C1. Further in some embodiments, as shown in FIG. 2, the rectangular ring is closed, which is advantageous for further improving the in-plane display brightness uniformity. In this case, there is one signal input portion 221, and one terminal of the signal input portion 221 is connected to the middle of one side of the rectangular ring; alternatively, as shown in FIG. 6A, there are two signal input portions 221, and terminals of the two signal input portions 221 are connected to two adjacent corners of the rectangular ring, and the other terminals of the two signal input portions 221 serve as the signal input terminals. The two signal input portions simultaneously introduce the input signals into the rectangular ring, so that the uniformity of the input signals can be improved.

Alternatively, as shown in FIG. 3, the rectangular ring has an opening on a side, and the opening may face to one side of the display panel where a flat cable is located, so as to prevent the flat cable from entering into the plane. In this case, the number of the signal input portions 221 is one, and one end of the signal input portion 221 is connected to one of two ends of the rectangular ring adjacent to the opening; alternatively, as shown in FIG. 6B, the number of the signal input portions 221 is two, terminals of the two signal input portions 221 are respectively connected to two ends of the rectangular ring adjacent to the opening, and the other terminals of the two signal input portions 221 are both used as the signal input terminals.

It should be noted that in the above embodiment, the out-of-plane electrode includes one outer electrode 22, and the voltage dividing structure is connected between the outer electrode 22 and the in-plane electrode 21, which is not limited by the embodiment of the present disclosure. In another optional embodiment, the out-of-plane electrode may include a plurality of outer electrodes sequentially arranged at intervals along a direction away from the in-plane electrode, and each outer electrode circumferentially extends along the contour of the in-plane electrode, wherein the outer electrode closest to the in-plane electrode is connected to the in-plane electrode; the voltage dividing structure is connected between every two adjacent outer electrodes. The voltage dividing structure is the same as the voltage dividing structure adopted in the above embodiment, and is not described again.

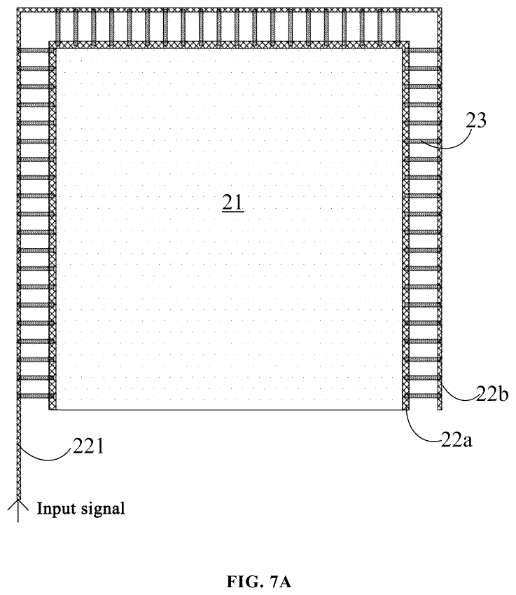

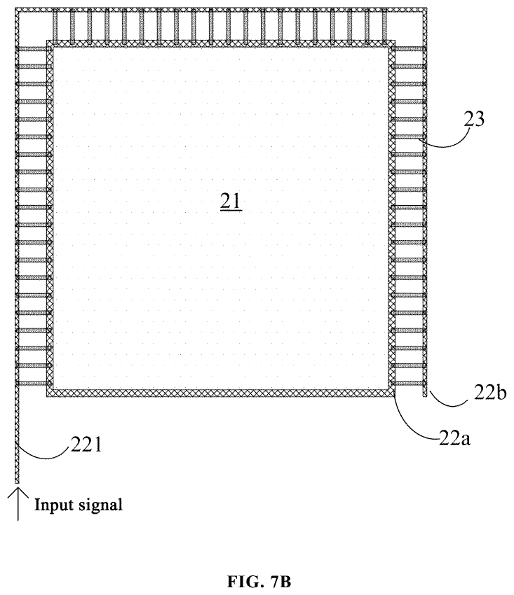

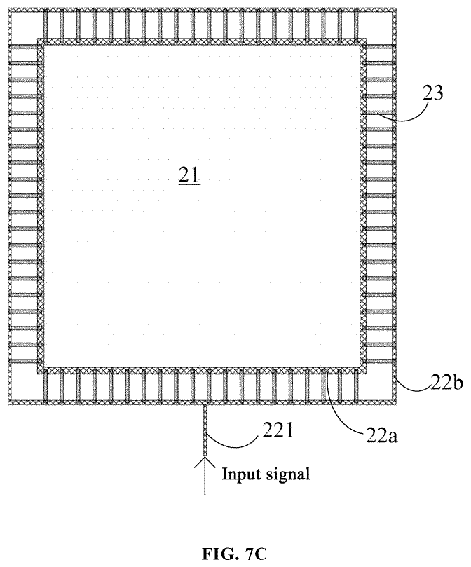

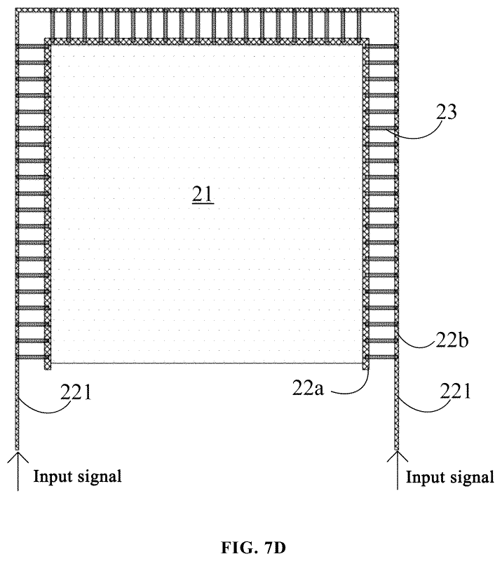

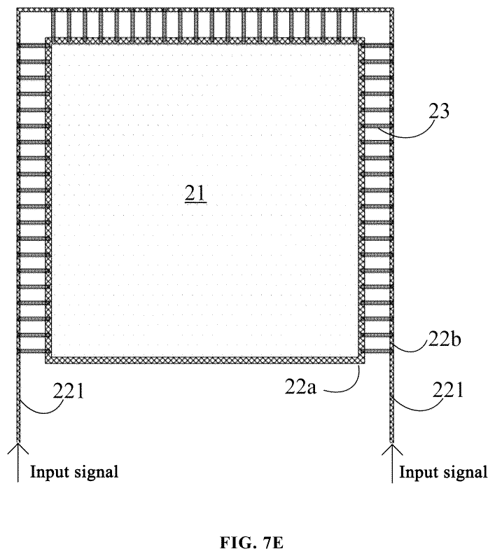

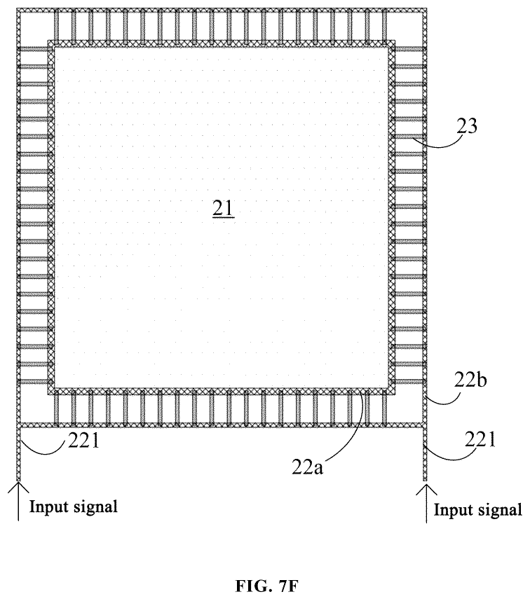

For example, as shown in FIG. 7A, the out-of-plane electrode may include two outer electrodes (22a, 22b) sequentially arranged at intervals along the direction away from the in-plane electrode 21, and each outer electrode circumferentially extends along the contour of the in-plane electrode, wherein the outer electrode 22a closest to the in-plane electrode 21 is connected to the in-plane electrode 21; the voltage dividing structure (i.e., the resistive elements 23) is connected between the two outer electrodes (22a, 22b).

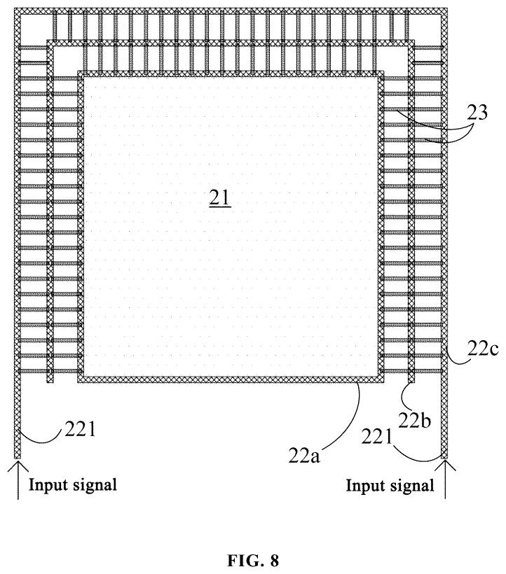

For another example, as shown in FIG. 8, the out-of-plane electrode may include three outer electrodes (22a, 22b, 22c) sequentially arranged at intervals along the direction away from the in-plane electrode 21, and each outer electrode circumferentially extends along the contour of the in-plane electrode, wherein the outer electrode 22a closest to the in-plane electrode 21 is connected to the in-plane electrode 21; the voltage dividing structures (i.e., the resistive elements 23) are connected between two adjacent outer electrodes (22a, 22b) and between two adjacent outer electrodes (22b, 22c).

The voltage dividing structure can be designed more flexibly by providing the plurality of outer electrodes and the voltage dividing structure between every two adjacent outer electrodes, so that the display brightness uniformity can be further improved. In practical applications, when a plurality of voltage dividing structures are included, every pair of two adjacent outer electrodes may be provided with the same voltage dividing structure therebetween; or different pairs of two adjacent outer electrodes may be provided with different voltage dividing structures therebetween. For example, the resistive elements in different voltage dividing structures may be identical in structure, and may be different in number.

With the plurality of outer electrodes, in some optional embodiments, the plurality of outer electrodes include at least one first outer electrode, that is a closed rectangular ring, and at least one second outer electrode. For example, as shown in FIGS. 7C and 7F, the two outer electrodes (22a, 22b) are the first outer electrodes; the second outer electrode is a rectangular ring with an opening on a side, and the corresponding openings of different second outer electrodes have the same orientation. For example, as shown in FIGS. 7A and 7D, the two outer electrodes (22a, 22b) are the second outer electrodes. That is, any one of the outer electrodes may optionally employ a closed rectangular ring or a rectangular ring having an opening on a side. For example, as shown in FIGS. 7B and 7E, one of the two outer electrodes (22a, 22b) is the first outer electrode, and the other is the second outer electrode.

With the plurality of outer electrodes, in some optional embodiments, the outer electrode (e.g., the outer electrode 22b) farthest from the in-plane electrode 21 is provided with a signal input portion 221, one end of the signal input portion 221 is connected to one side of the rectangular ring, and the other end serves as the signal input terminal. Further in some embodiments, the outer electrode (for example, the outer electrode 22b) farthest from the in-plane electrode 21 is the first outer electrode, that is, a closed rectangular ring. In this case, as shown in FIG. 7C, the number of the signal input portions 221 is one, and one end of the signal input portion 221 is connected to the middle of one side of the rectangular ring; alternatively, as shown in FIG. 7F, the number of the signal input portions 221 is two, and terminals of the two signal input portions 221 are connected to two adjacent corners of the rectangular ring, and the other terminals of the two signal input portions 221 serve as the signal input terminals.

In other optional embodiments, the outer electrode (for example, the outer electrode 22B) farthest from the in-plane electrode is the second outer electrode, that is, the rectangular ring having an opening on a side. In this case, as shown in FIG. 7B, the number of the signal input portions 221 is one, and one end of the signal input portion 221 is connected to one of two ends of the rectangular ring adjacent to the opening; alternatively, as shown in FIG. 7D, the number of the signal input portions 221 is two, terminals of the two signal input portions 221 are respectively connected to two ends of the rectangular ring adjacent to the opening, and the other terminals of the two signal input portions 221 are both used as the signal input terminals.

It should be noted that in practical applications, no matter the number of the outer electrodes is one or more, the input signal may be introduced to the out-of-plane electrode by using other signal input structures and in other input manners, which is not particularly limited in the embodiment of the present disclosure.

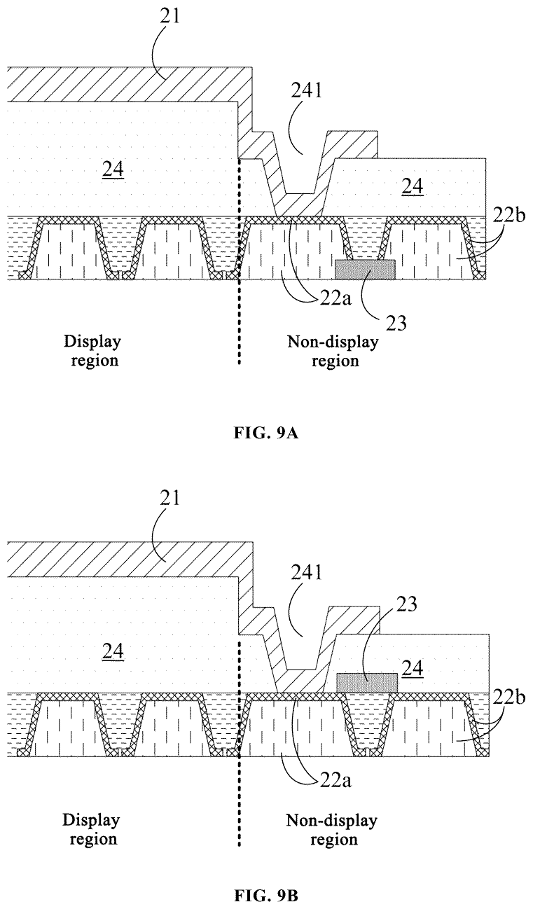

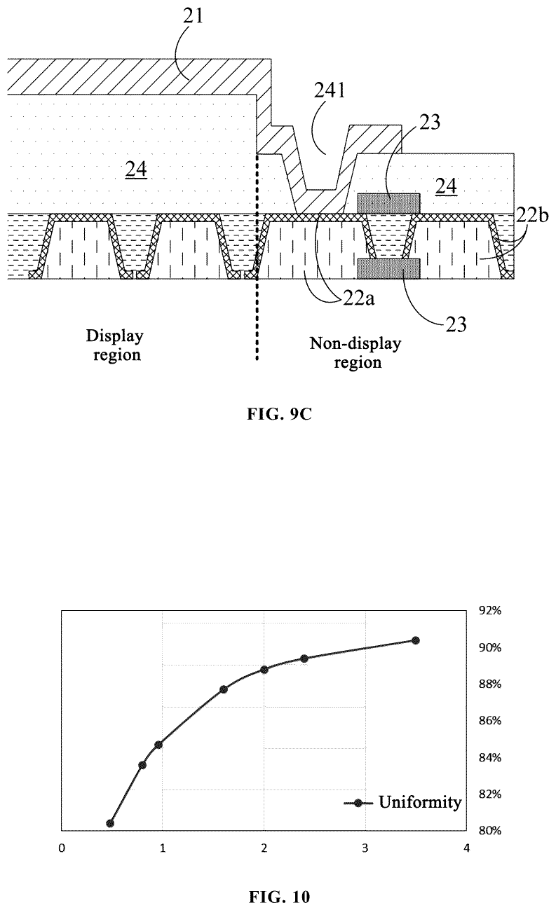

With the plurality of outer electrodes, in some optional embodiments, as shown in FIG. 9A, taking two outer electrodes as an example, the resistive element 23 and the two outer electrodes (22a, 22b) connected to the resistive element 23 are disposed in the same layer, and a part of the two outer electrodes (22a, 22b) connected to the resistive element 23 is stacked on a side of the voltage dividing structure (22a, 22b) away from the base (not shown), so that the voltage dividing structure may be connected to the two outer electrodes (22a, 22b), respectively. Specifically, an orthographic projection of two ends of each resistive element 23 on the plane parallel to the display region and orthographic projections of the two outer electrodes on the plane parallel to the display region has an overlapping area, a shape and a size of the overlapping area may be set according to specific needs, as long as good electrical connection between the two ends of each resistive element 23 and the two outer electrodes (22a, 22b) can be ensured, which is not particularly limited in the embodiment of the present disclosure. In other optional embodiments, as shown in FIG. 9B, the resistive element 23 and the two outer electrodes (22a, 22b) connected to the resistive element 23 are arranged in different layers, and two ends of the resistive element 23 are respectively stacked on a side of the two outer electrodes (22a, 22b) connected to the resistive element 23 away from the base, which can also realize the connection between the resistive element 23 and the two outer electrodes (22a, 22b). In other optional embodiments, as shown in FIG. 9C, the plurality of resistive elements 23 are divided into two layers in a direction perpendicular to a plane where the base is located, wherein the resistive element 23 in one layer and the two outer electrodes (22a, 22b) connected to the resistive element 23 are arranged in the same layer, and a part of the two outer electrodes (22a, 22b) connected to the resistive element 23 is stacked on the side of the resistive element 23 away from the base; the resistive element 23 in the other layer and the two outer electrodes (22a, 22b) connected to the resistive element are arranged in different layers, and two ends of the resistive element 23 are respectively stacked on a side of the two outer electrodes (22a, 22b) connected to the resistive element away from the base. By using two layers of resistive elements, the number of resistive elements 23 can be increased under the same space, and the uniformity of the voltage drop of the in-plane electrode 21 among the positions connected to the resistive elements 23 can be further improved.

With the plurality of outer electrodes, in some optional embodiments, as shown in FIGS. 9A to 9C, the display panel further includes an encapsulation layer 24, the encapsulation layer 24 covers the display region and the non-display region, and the in-plane electrode 21 and the out-plane electrode are located on two sides of the encapsulation layer 24 away from and close to the base, respectively; that is, the in-plane electrode 21 is located on a side of the encapsulation layer 24 away from the base; and the out-plane electrode is located on a side of the encapsulation layer 24 close to the base. The encapsulation layer 24 further includes a plurality of vias 241, and the in-plane electrode 21 is connected to the outer electrode 22a closest to the in-plane electrode through the plurality of vias 241. Alternatively, in practical applications, the in-plane electrode 21 is connected to the outer electrode 22a closest to the in-plane electrode 21 in any other manner, which is not particularly limited by the embodiment of the present disclosure.

It should be noted that the number and the structure of the vias 241 may be set according to specific needs. For example, as an example, the shape of the contour of the in-plane electrode 21 is rectangular, the vias 241 may be three long bar-shaped vias, and are respectively arranged parallel to the corresponding three sides of the in-plane electrode 21 except for a side where the flat cable of the display panel is located, which is not particularly limited by the embodiment of the present disclosure.

With one outer electrode, in some optional embodiments, the display panel further includes an encapsulation layer, which covers the display region and the non-display region, and the in-plane electrode and the out-plane electrode are located on two sides of the encapsulation layer away from and close to the base, respectively; that is, the in-plane electrode is located on a side of the encapsulation layer away from the base; and the out-plane electrode is located on a side of the encapsulation layer close to the base. The encapsulation layer includes a plurality of vias, and the in-plane electrode is connected to one end of each resistive element 23 through the plurality of vias. For example, the structure of the encapsulation layer is the same as that of the encapsulation layer 24 shown in FIGS. 9A to 9C. Further in some embodiments, the other end of each resistive element 23 is disposed in the same layer as the outer electrode 22, and a part of the outer electrode 22 is stacked on a side of the resistive element 23 away from the base, so that the connection between the resistive element 23 and the outer electrode can be realized. Specifically, an orthographic projection of two ends of each resistive element 23 on the plane parallel to the display region and orthographic projections of the in-plane electrode and the outer electrode on the plane parallel to the display region has an overlapping area, a shape and a size of the overlapping area may be set according to specific needs, as long as good electrical connection between the two ends of each resistive element and the in-plane electrode and the outer electrode can be ensured, which is not particularly limited in the embodiment of the present disclosure. In other optional embodiments, one end of the resistive element 23 and the outer electrode are arranged in different layers, and the other end of the resistive element 23 is stacked on a side of the outer electrode away from the base, which can also realize the connection between the resistive element 23 and the outer electrode. In other optional embodiments, the plurality of resistive elements 23 are divided into two layers in a direction perpendicular to a plane where the base is located, wherein the resistive element 23 in one layer and the outer electrode 22 are arranged in the same layer, and a part of the outer electrode 22 is stacked on the side of the resistive element 23 away from the base; the resistive element 23 in the other layer and the outer electrode 22 are arranged in different layers, and one end of the resistive element 23 is stacked on a side of the outer electrode 22 away from the base. That is, the voltage dividing structure may be connected to the in-plane electrode through the outer electrode, or may be directly connected to the in-plane electrode. In practical applications, one of the above two structures may be selected as needed.

It should be noted that in practical applications, in order to further reduce the voltage drop across the out-of-plane electrode, an overall thickness of the out-of-plane electrode may be increased, and/or a width of the out-of-plane electrode may be increased on the premise that a width of the non-display region of the display panel meets the requirement.

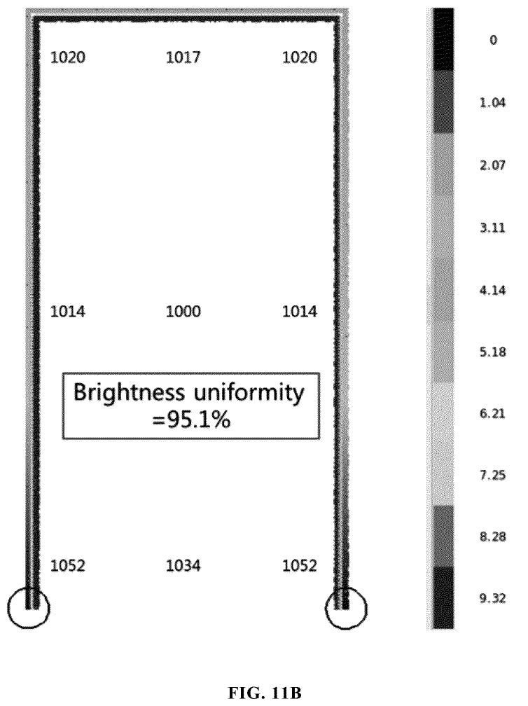

FIG. 11A is a schematic diagram showing a distribution of a display brightness of a display panel using the cathode ring shown in FIG. 1 in the prior art; and FIG. 11B is a schematic diagram showing a distribution of a display brightness of a display panel employing two outer electrodes and a voltage dividing structure according to embodiments of the present disclosure. As can be seen from a comparison between FIG. 11A and FIG. 11B, in the prior art, brightness values of nine different positions of the display region of the display panel have a large difference among them, and the brightness uniformity is 80.6%. Compared with the prior art, in the embodiment of the present disclosure, the difference among the brightness values of nine different positions of the display region of the display panel adopting the two outer electrodes and the voltage dividing structure is obviously reduced, and the brightness uniformity reaches 95.1%. Therefore, the display panel provided by the embodiment of the present disclosure can effectively improve the display brightness uniformity.

In summary, in the display panel provided in the embodiments of the present disclosure, the voltage dividing structure is connected between the in-plane electrode and the out-of-plane electrode, and a resistivity of a material of the voltage dividing structure is greater than that of the out-of-plane electrode and the in-plane electrode. By having the resistivity of the material of the voltage dividing structure greater than that of the out-of-plane electrode and the in-plane electrode, a total resistance on paths from an signal input terminal of the out-of-plane electrode to signal output terminals (i.e., the terminals at which the respective resistive elements 23 are connected to the in-plane electrode 21) may be approximately equal to an equivalent resistance of the voltage dividing structure, i.e., the difference in resistance among the paths corresponding to the respective signal output terminals can be compensated for, and further the voltage drops (IR drops) from the signal input terminal of the out-of-plane electrode to the plurality of signal output terminals corresponding to a plurality of different positions of the in-plane electrode 21 in the circumferential direction thereof can be substantially the same, whereby the display brightness uniformity can be improved. Meanwhile, the out-of-plane electrode does not increase the width of the non-display region of the display panel on the whole, so that the narrow frame is realized.

As another technical solution, embodiments of the present disclosure further provide a display apparatus, which includes the display panel provided in the embodiment of the present disclosure.

In the display apparatus provided by the embodiment of the present disclosure, by adopting the display panel provided by the embodiment of the present disclosure, the current difference in different pixel regions (that is, the display brightness difference) can be eliminated, and the display brightness uniformity can be improved. Meanwhile, the width of the non-display region of the display panel cannot be increased, so that the narrow frame is realized.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display panel, comprising a display region and a non-display region surrounding the display region, wherein the display panel comprises a light emitting device comprising a first electrode, the first electrode comprises an in-plane electrode in the display region and an out-of-plane electrode in the non-display region, and a voltage dividing structure, wherein the voltage dividing structure is connected between the in-plane electrode and the out-of-plane electrode, and
a resistivity of a material of the voltage dividing structure is greater than that of a material of each of the out-of-plane electrode and the in-plane electrode.

2. The display panel according to claim 1, wherein the voltage dividing structure is arranged such that voltage drops from a signal input terminal of the out-of-plane electrode to a plurality of signal output terminals at a plurality of different positions in a circumferential direction of the in-plane electrode are the same; and
the voltage dividing structure comprises a plurality of resistive elements arranged at intervals along an extending direction of the out-of-plane electrode, and each of the plurality of resistive elements had one end connected to the out-of-plane electrode, and the other end being the signal output terminal connected to the in-plane electrode at a corresponding one of the plurality of different positions in the circumferential direction of the in-plane electrode.

3. (canceled)

4. The display panel according to claim 2, wherein a resistance of each of the plurality of resistive elements is a first resistance, and the first resistances of the plurality of the resistive elements are the same and arranged at equal intervals; a resistance of a path from the signal input terminal of the out-of-plane electrode to each of the plurality of signal output terminals is a second resistance, and the first resistance is greater than the second resistance.

5. The display panel according to claim 2, wherein at least some of the plurality of resistive elements have different resistances and are arranged at equal intervals; or at least some of the plurality of resistive elements have different resistances and are arranged at unequal intervals.

6. The display panel according to claim 5, wherein the out-of-plane electrode is a closed rectangular ring or a rectangular ring with an opening on a side; at least some of the resistive elements on at least one side of the rectangular ring have different resistances; and
orthographic projections of the at least some of the resistive elements on the at least one side of the rectangular ring on a plane parallel to the display region have different areas; and
a shape of an orthographic projection of each of the plurality of resistive elements on the plane parallel to the display region comprises a bar shape, and the at least some of the resistive elements on the at least one side of the rectangular ring have the same length in an extending direction of the at least some of the resistive elements but have different widths.

7. (canceled)

8. The display panel according to claim 2, wherein a shape of an orthographic projection of each of the plurality of resistive elements on a plane parallel to the display region comprises a bar shape, which is a meander line; and
the meander line comprises a plurality of straight line segments sequentially connected together;
an angle between every two adjacent straight line segments is equal to 90°; and one of every two adjacent straight segments is perpendicular to the extending direction of the out-of-plane electrode and the other of the every two adjacent straight line segments is parallel to the extending direction of the out-of-plane electrode; or
an angle between every two adjacent straight line segments is less than or equal to 90′; and the angle between each of the every two adjacent straight line segments and the extending direction of the out-of-plane electrode is less than 90°.

9. (canceled)

10. The display panel according to claim 2, wherein a shape of an orthographic projection of each of the plurality of resistive elements on a plane parallel to the display region comprises a bar shape, which is a meander line; and
the meander line comprises a plurality of arc segments connected sequentially together, and every two adjacent arc segments constitute an S-shaped arc segment.

11. (canceled)

12. The display panel according to claim 2, wherein the out-of-plane electrode comprises one outer electrode circumferentially extending along a contour of the in-plane electrode, and the voltage dividing structure is connected between the outer electrode and the in-plane electrode.

13. The display panel according to claim 2, wherein the out-of-plane electrode comprises a plurality of outer electrodes sequentially arranged at intervals in a direction away from the in-plane electrode, each outer electrode extends circumferentially along a contour of the in-plane electrode; and the outer electrode closest to the in-plane electrode is connected to the in-plane electrode; and
the voltage dividing structure is connected between every two adjacent outer electrodes; and
the plurality of outer electrodes comprise at least one first outer electrode and at least one second outer electrode, the first outer electrode is a closed rectangular ring; the second outer electrode is a rectangular ring with an opening on a side, and the openings corresponding to different second outer electrodes have a same orientation.

14. (canceled)

15. The display panel according to claim 13, wherein the outer electrode farthest from the in-plane electrode comprises at least one signal input portion each having one end connected to one side of the rectangular ring and the other end serving as the signal input terminal.

16. The display panel according to claim 15, wherein the outer electrode farthest from the in-plane electrode is the first outer electrode;
the at least one signal input portion comprises one signal input portion, and one end of the signal input portion is connected to a middle position at one side of the rectangular ring; or
the at least one signal input portion comprises two signal input portions, and ends of the two signal input portions are connected to two adjacent corners of the rectangular ring, respectively, and the other ends of the two signal input portions each are the signal input terminal.

17. The display panel according to claim 15, wherein the outer electrode farthest from the in-plane electrode is the second outer electrode;
the at least one signal input portion comprises one signal input portion, and one end of the signal input portion is connected to one of two ends of the rectangular ring adjacent to the opening; or
the at least one signal input portion comprises two signal input portions, ends of the two signal input portions are connected to two ends of the rectangular ring adjacent to the opening, and the other ends of the two signal input portions each are the signal input terminal.

18. The display panel according to claim 13, wherein the light emitting device further comprises:
a base; and
a second electrode and an organic functional layer; wherein the second electrode, the organic functional layer and the in-plane electrode are all in the display region and are sequentially stacked on a side of the base along a direction away from the base; and the first electrode is one of a cathode and an anode, and the second electrode is the other of the cathode and the anode.

19. The display panel according to claim 18, wherein each resistive element and two outer electrodes connected to the resistive element are in a same layer, and a part of the two outer electrodes connected to the resistive element is stacked on a side of the resistive element away from the base; or
each resistive element and the two outer electrodes connected to the resistive element are in different layers, and two ends of the resistive element are respectively stacked on a side of the two outer electrodes connected to the resistive element away from the base.

20. The display panel according to claim 18, wherein the plurality of resistive elements are divided into two layers in a direction perpendicular to a plane where the base is located, wherein in one of the two layers, each resistive element and two outer electrodes connected to the resistive element are in a same layer, and a part of the two outer electrodes connected to the resistive element is stacked on a side of the resistive element away from the base; and in the other of the two layers, each resistive element and two outer electrodes connected to the resistive element are in different layers, and two ends of the resistive element are respectively stacked on a side of the two outer electrodes connected to the resistive element away from the base.

21. The display panel according to claim 18, wherein the display panel further comprises an encapsulation layer covering the display region and the non-display region, and the in-plane electrode and the out-of-plane electrode are on two sides of the encapsulation layer away from and close to the base, respectively; and
the encapsulation layer comprises a plurality of vias, and the in-plane electrode is connected to the outer electrode closest to the in-plane electrode through the plurality of vias.

22. The display panel according to claim 12, wherein the light emitting device further comprises:
a base;
a second electrode and an organic functional layer; wherein the second electrode, the organic functional layer and the in-plane electrode are all in the display region and are sequentially stacked on a side of the base along a direction away from the base; wherein the first electrode is one of a cathode and an anode, and the second electrode is the other of the cathode and the anode; and
an encapsulation layer covering the display region and the non-display region, and the in-plane electrode and the out-of-plane electrode are on two sides of the encapsulation layer away from and close to the base, respectively; wherein the encapsulation layer comprises a plurality of vias, and the in-plane electrode is connected to the voltage dividing structure through the plurality of vias.

23. The display panel according to claim 22, wherein the resistive element and the outer electrode are in a same layer, and a part of the outer electrode is stacked on a side of the resistive element away from the base; or
the resistive element and the outer electrode are in different layers, and one end of the resistive element is stacked on a side of the outer electrode away from the base.

24. The display panel according to claim 22, wherein the plurality of resistive elements are divided into two layers in a direction perpendicular to a plane where the base is located, wherein in one of the two layers, the resistive element and the outer electrode are in a same layer, and a part of the outer electrode is stacked on the side of the resistive element away from the base; and in the other of the two layers, the resistive element and the outer electrode are in different layers, and one ends of the resistive element is stacked on a side of the outer electrode away from the base.

25. (canceled)

26. A display apparatus, comprising the display panel according to claim 1.
